(19) United States
(12) Patent Application Publication
(10) Pub. No.: US 2004/0041244 A1
(43) Pub. Date: Mar. 4, 2004

(54) Low expansion plate, method of manufacturing the same, and semiconductor device using the low expansion plate

(76) Inventors: Tomohei Sugiyama, Aichi-ken (JP); Kyoichi Kinoshita, Aichi-ken (JP); Takashi Yoshida, Aichi-ken (JP); Hidehiro Kudo, Aichi-ken (JP); Eiji Kono, Aichi-ken (JP)

Correspondence Address: MORGAN & FINNEGAN, L.L.P., 345 Park Avenue, New York, NY, 10154, US

(21) Appl. No.: 10/636,800

(22) Filed: Aug. 7, 2003

(30) Foreign Application Priority Data
Aug. 27, 2002 (JP) 2002-246869

(51) Int. Cl. H01L 23/495

(52) U.S. Cl. 257/675

(57) ABSTRACT

In a low expansion plate according to the present invention, a Cu member is made to fill the inside of each of through-holes of a perforated plate made of Invar and also to cover both surfaces of the perforated plate. On both surfaces of the Cu member, a concave portion is formed in each portion corresponding to each of the through-holes of the perforated plate and a convex portion is formed in each portion where Invar constituting the perforated plate exists.

### BACKGROUND OF THE INVENTION

1. Field of the Invention

The present invention relates to a low expansion plate, in particular, a low expansion plate used as a heat spreader of a semiconductor device or the like.

The present invention also relates to a method of manufacturing the above-mentioned low expansion plate and a semiconductor device using the above-mentioned low expansion plate.

2. Description of the Related Art

A structure of a conventional semiconductor device is shown in FIG. 6. On a surface of a substrate 1 made of Al, an insulating layer 2 is formed. A semiconductor element 4 is bonded through solder 3 onto a wiring layer (not shown) formed on the surface of the insulating layer 2.

With the substrate 1 made of Al which has excellent heat conductivity, heat generated in the semiconductor element 4 is transmitted through the insulating layer 2 to the substrate 1 and is then efficiently radiated from the substrate 1 to the outside.

However, a semiconductor material such as Si which is used in the semiconductor element 4 has a small thermal expansion coefficient, while Al constituting the substrate 1 has a large thermal expansion coefficient. The difference in thermal expansion coefficient is known to bring thermal stress between the substrate 1 and the semiconductor element 4 upon temperature change. When the thermal stress becomes large, there appears a risk that the semiconductor element 4 is warped and the solder 3 for bonding the semiconductor element 4 is cracked.

As shown in FIG. 7, in an attempt to ease this thermal stress, semiconductor devices used in an environment with a wide temperature range, for example, in automobiles, have a heat spreader 5 installed between the semiconductor element 4 and the insulating layer 2.

As shown in FIG. 8, for example, a composite member is used as the heat spreader 5, in which both surfaces of a perforated plate 6 made of Invar and having a number of through-holes H are surrounded by a Cu member 7. Invar constituting the perforated plate 6 is an alloy having an extremely small thermal expansion coefficient, which hardly exhibits heat expansion around a room temperature. Therefore, the semiconductor element 4 is mounted on the heat spreader 5 to thereby ease the thermal stress. Also, the Cu member 7 superior in heat conductivity penetrates into each of the through-holes H of the perforated plate 6, so that a heat radiation property is ensured by use of the Cu member 7.

However, as shown in FIG. 8, the Cu member 7 in a portion A where the through-hole H is formed in the perforated plate 6 is formed with a larger thickness corresponding to the thickness of the perforated plate 6 as compared with the Cu member 7 in a portion B where Invar constituting the perforated plate 6 exists. Accordingly, when the Cu member 7 undergoes the thermal expansion upon temperature rise, as shown in FIG. 9, a thermal deformation amount of the portion A where the through-hole H of the perforated plate 6 is formed becomes larger than that of the remaining portion B in the thickness direction. As a result, a shearing stress develops in the thickness direction, which involves a risk that the solder 3 used for bonding of both surfaces of the heat spreader 5 is cracked.

### SUMMARY OF THE INVENTION

The present invention has been made to solve the above-mentioned problems, and an object of the present invention is therefore to provide a low expansion plate capable of preventing a shearing stress from developing in a thickness direction thereof.

Also, another object of the present invention is to provide a method of manufacturing a low expansion plate for obtaining the above-mentioned low expansion plate, and a semiconductor device using the low expansion plate.

A low expansion plate according to the present invention includes:

a planar perforated plate made of low expansion material in which a plurality of through-holes are formed; and

a metal member filling the inside of the respective thorough-holes of the perforated plate and surrounding both surfaces of the perforated plate,

on at least one of both surfaces of the metal member, one of a concave portion and a convex portion being formed in each portion corresponding to each of the through-holes of the perforated plate while the other of the concave portion and the convex portion being formed in each portion corresponding to an area other than the through-holes of the perforated plate, all the convex portions being identical in thermal expansion coefficient in a plate thickness direction.

Also, a method of manufacturing a low expansion plate according to the present invention includes:

arranging a planar metal plate on each of both surfaces of a planar perforated plate made of low expansion material in which a plurality of through-holes are formed;

arranging a protective member on each surface of the metal plates opposite to the perforated plate;

pressurizing the protective members from each surface thereof opposite to the metal plates to depress the metal plates toward the inside of the respective thorough-holes of the perforated plate and to bond the metal plates onto both surfaces of the perforated plate; and

removing the protective members from outer surfaces of the metal plates.

Further, a semiconductor device according to the present invention includes:

a low expansion plate; and

a semiconductor element disposed on the concave portion and the convex portion formed on the surface of the metal member of the low expansion plate.

### BRIEF DESCRIPTION OF THE DRAWINGS

FIG. 1 is a sectional view showing a structure of a low expansion plate in accordance with Embodiment 1 of the present invention;

FIG. 2 is a sectional view showing a structure of a semiconductor device using the low expansion plate in accordance with Embodiment 1;

FIGS. 3a and 3b are sectional views illustrating a method of manufacturing the low expansion plate in accordance with Embodiment 1;

FIG. 4 is a sectional view showing a structure of a low expansion plate in accordance with Embodiment 2 of the present invention;

FIG. 5 is a sectional view showing a structure of a semiconductor device using the low expansion plate in accordance with Embodiment 2;

FIG. 6 is a sectional view showing a structure of a conventional semiconductor device;

FIG. 7 is a sectional view showing a structure of another conventional semiconductor device;

FIG. 8 is a sectional view showing a structure of a heat spreader of the semiconductor device of FIG. 7; and

FIG. 9 is a sectional view showing a state of the heat spreader upon temperature rise in the semiconductor device of FIG. 7.

### DESCRIPTION OF THE PREFERRED EMBODIEMENTS

Embodiment 1:

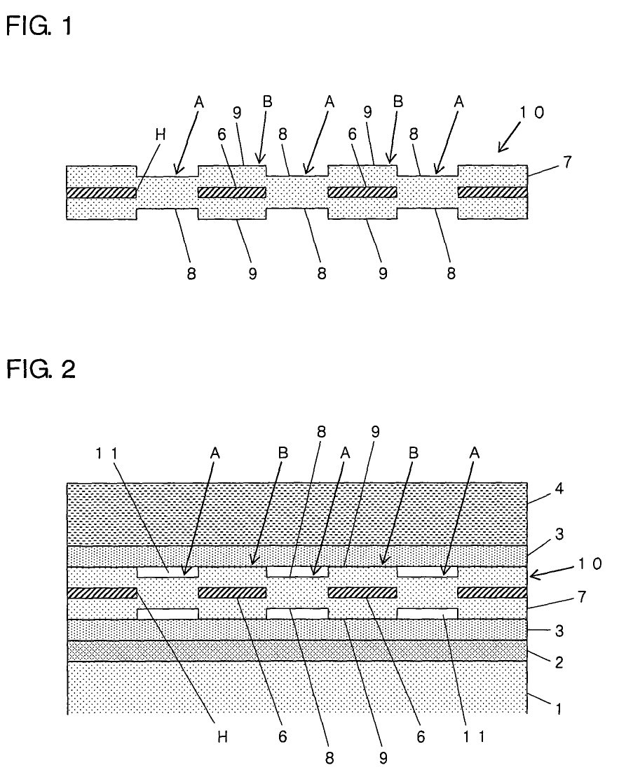

The section of a low expansion plate 10 according to Embodiment 1 is shown in FIG. 1. A planar perforated plate 6 made of Invar and having a number of through-holes H therein is surrounded by a Cu member 7. The Cu member 7 fills the inside of the respective through-holes H of the perforated plate 6 and surrounds both surfaces of the perforated plate 6. The Cu member 7 has a concave portion 8 formed in each portion A corresponding to each of the through-holes H of the perforated plate 6 and a convex portion 9 formed in each portion B where Invar constituting the perforated plate 6 exists on both surfaces thereof.

FIG. 2 shows the structure of a semiconductor device in which the low expansion plate 10 having the above-mentioned structure is used as a heat spreader. An insulating layer 2 is formed on the surface of a substrate 1 made of Al. The bottom surface of the Cu member 7 of the low expansion plate 10 is bonded thorough solder 3 on a wiring layer (not shown) formed on the top surface of the insulating layer 2. Further, a semiconductor element 4 is bonded thorough another solder 3 on the top surface of the Cu member 7 of the low expansion plate 10.

Here, the Cu member 7 of the low expansion plate 10 has the concave portions 8 and the convex portions 9 formed on both surfaces thereof. Therefore, only the convex portions 9 are in contact with the solder 3, and the concave portions 8 are sealed with the surface of the solder 3 to form void portions 11. That is, every portion of the Cu member 7 bonded with the solder 3 corresponds to the portion B where Invar constituting the perforated plate 6 exists, and has the identical thermal expansion coefficient in the thickness direction.

Accordingly, even when the thermal expansion is caused in the Cu member 7 of the low expansion plate 10 upon temperature rise, thermal deformation amounts of the portions bonded with the solder 3 in the thickness direction are equal to each other, so that no shearing stress in the thickness direction is generated. Consequently, cracking of the solder 3 used for the bonding of both surfaces of the low expansion plate 10 can be prevented.

Also, the Cu member 7 of the low expansion plate 10 has superior heat conductivity. Therefore, heat generated in the semiconductor element 4 propagates to the Cu member 7 in the portion B bonded to the semiconductor element 4 with the solder 3. And the heat passes through the Cu member 7 in the adjacent portion A and then propagates again to the Cu member 7 in the portion B. After that, the heat passes through the insulating layer 2 bonded to the Cu member 7 in the portion B with the solder 3 and then propagates to the substrate 1. Since the substrate 1 is made of Al which is superior in heat conductivity, the heat is efficiently radiated from the substrate 1 to the outside.

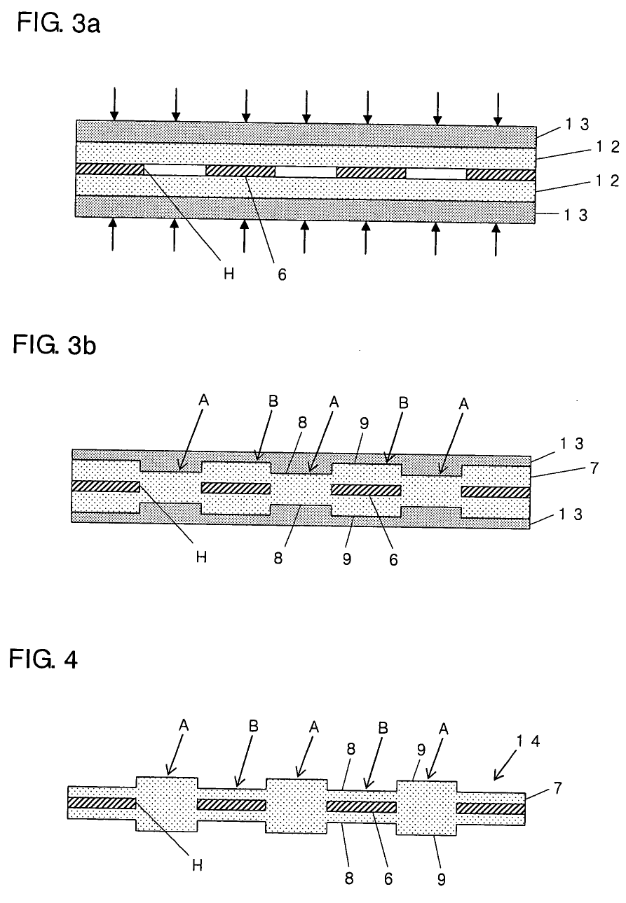

Now, a method of manufacturing the above-mentioned low expansion plate 10 is described. As shown in FIG. 3a, a Cu plate 12 is arranged on each of the surfaces of the perforated plate 6 having a number of through-holes H formed therein. Further, a planar protective member 13 is arranged on each of the outer surfaces of the Cu plates 12, that is, on each surface opposite to the perforated plate 6. At this time, for the material of the protective member 13, it is preferable to use, for example, pure Fe or Al having a Young's modulus smaller than that of Invar constituting the perforated plate 6 and that of Cu which is the material for the Cu plate 12.

Next, the Cu plates 12 are deformed by the pressurization from the surfaces of the protective members 13 opposite to the Cu plates 12. As shown in FIG. 3b, the Cu plates 12 are depressed so as to penetrate into the through-holes H of the perforated plate 6, so that the Cu member 7 bonded to both surfaces of the perforated plate 6 is formed. After that, the protective members 13 are peeled and removed from the outer surfaces of the Cu member 7. As a result, as shown in FIG. 1, the low expansion plate 10 is manufactured in which the concave portions 8 and the convex portions 9 are formed on the surfaces thereof. The thickness of the low expansion plate 10 is preferably 0.1 to 5 mm.

Embodiment 2:

In FIG. 4, the section of a low expansion plate 14 according to Embodiment 2 is shown. Similar to the low expansion plate 10 according to Embodiment 1 shown in FIG. 1, the low expansion plate 14 includes: the planar perforated plate 6 made of Invar and having a number of through-holes H formed therein; and the Cu member 7 covering both surfaces of the perforated plate 6 while filling the inside of the respective through-holes H of the perforated plate 6. Here, in the low expansion plate 10 according to Embodiment 1, on both surfaces of the Cu member 7, the concave portion 8 is formed in each portion A corresponding to each of the through-holes H of the perforated plate 6, and the convex portion 9 is formed in each portion B where Invar constituting the perforated plate 6 exists. On the contrary, in the low expansion plate 14 according to Embodiment 2, on both surfaces of the Cu member 7, the convex portion 9 is formed in each portion A corresponding to each of the through-holes H of the perforated plate 6, and the concave portion 8 is formed in each portion B where Invar constituting the perforated plate 6 exists.

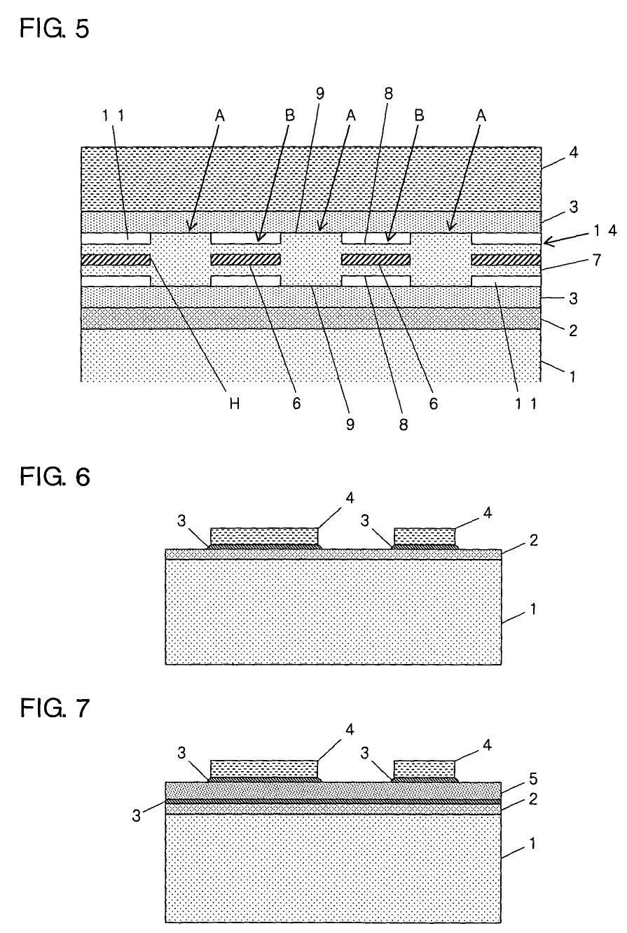

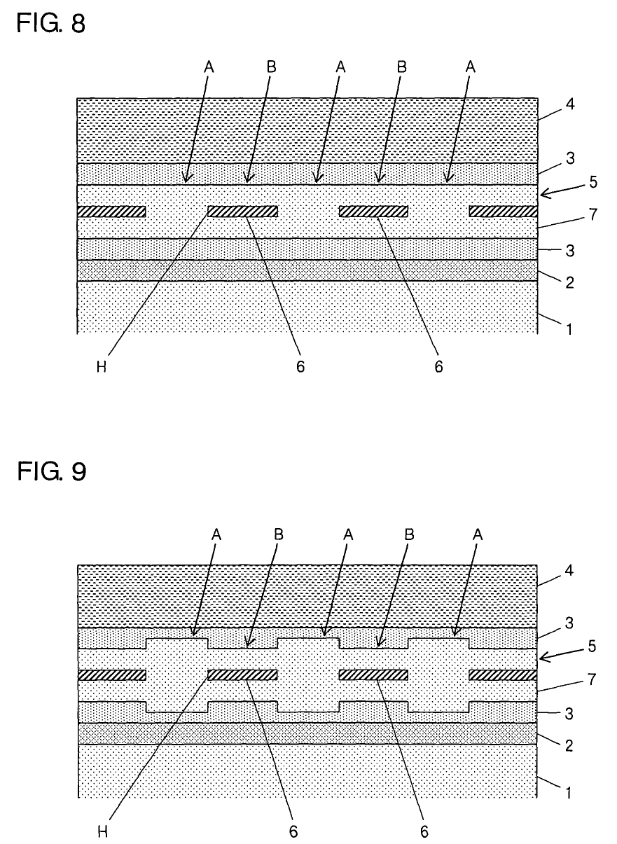

By using the low expansion plate 14 according to Embodiment 2 as a heat spreader, a semiconductor device similar to that shown in FIG. 2 is manufactured. As shown in FIG. 5, only the convex portions 9 are in contact with the solder 3, and the concave portions 8 are sealed with the surface of the solder 3 to form the void portions 11. Therefore, every portion of the Cu member 7 bonded with the solder 3 is the portion A corresponding to each of the through-holes H of the perforated plate 6, and has the identical thermal expansion coefficient in the thickness direction.

Accordingly, even when the thermal expansion is caused in the Cu member 7 upon temperature rise, no shearing stress in the thickness direction is generated. Consequently, cracking of the solder 3 used for the bonding of both surfaces of the low expansion plate 14 can be prevented.

Heat generated in the semiconductor element 4 during operation of the semiconductor device propagates to the Cu member 7 in the portion A bonded to the semiconductor element 4 with the solder 3. After that, the heat passes through the insulating layer 2 and propagates to the substrate 1. Then, the heat is efficiently radiated from the substrate 1 to the outside.

For example, the low expansion plate 14 according to Embodiment 2 can be manufactured by extruding Cu into each of the through-holes H of the perforated plate 6 made of Inver.

It should be noted here that the difference in height between the concave portions 8 and the convex portions 9 may be small as far as the concave portions 8 are not bonded with the solder 3 in a case where the convex portions 9 on each surface of the Cu member 7 are bonded to the semiconductor element 4 or the like through the solder 3. While taking into consideration wettability of the solder 3, the difference in height may be about 5 to 10 μm or larger, for instance. However, if the concave portions 8 are likely to be bonded with the solder 3, it is preferable that a solder resist or the like is applied to the concave portions 8 to prevent the bonding with the solder 3.

The low expansion plate according to the present invention can be used as a substrate of a semiconductor device. In this case, it is not necessary to form the concave portions 8 and the convex portions 9 on both surfaces of the Cu member 7, the concave portions 8 and the convex portions 9 may be formed on one of the surfaces, which is bonded to the semiconductor element.

The material for the perforated plate 6 is not limited to Invar. It is also possible to use Mo, an Fe—Ni-based alloy, or other low expansion materials. Further, the metal material surrounding the perforated plate 6 is not limited to Cu. But, in a case where the low expansion plate is used as a heat spreader or a substrate of the semiconductor device, a metal member such as an Al member having superior heat conductivity is preferred.

As described above, in the low expansion plate according to the present invention, on the surface of the metal member filling the inside of the respective through-holes of the perforated plate made of the low expansion material and covering both surfaces of the perforated plate, one of the concave portion and the convex portion is formed in the portion corresponding to each of the through-holes of the perforated plate while the other of the concave portion and the convex portion is formed in the portion corresponding to an area other than the through-holes of the perforated plate. Consequently, generation of shearing stress in the thickness direction due to thermal expansion can be prevented even when the surfaces are bonded by the solder or the like.

Such a low expansion plate can be manufactured by: arranging the planer metal plate on each of both surfaces of the planar perforated plate made of the low expansion material; arranging the protective member on each surface of the metal plates opposite to the perforated plate; pressurizing the protective members from each surface of the protective members opposite to the metal plates to depress the metal plates toward the inside of the respective through-holes of the perforated plate and to bond the metal plates to both surfaces of the perforated plate; and thereafter removing the protective members from the outer surfaces of the metal plates.

Furthermore, in the semiconductor device according to the present invention, the semiconductor element is bonded on the concave portions and the convex portions formed on the surface of the metal member of the above-mentioned low expansion plate. Therefore, no shearing stress due to thermal expansion in the thickness direction is generated. As a result, the effect is attained in which the fear of cracking of the solder or the like used for the bonding can be eliminated.

What is claimed is:

1. A low expansion plate comprising:
a planar perforated plate made of low expansion material in which a plurality of through-holes are formed; and
a metal member filling the inside of the respective thorough-holes of the perforated plate and surrounding both surfaces of the perforated plate,
on at least one of both surfaces of the metal member, one of a concave portion and a convex portion being formed in each portion corresponding to each of the through-holes of the perforated plate while the other of the concave portion and the convex portion being formed in each portion corresponding to an area other than the through-holes of the perforated plate, all the convex portions being identical in thermal expansion coefficient in a plate thickness direction.

2. A low expansion plate according to claim 1, wherein the concave portion is formed in the portion corresponding to each of the through-holes of the perforated plate while the convex portion is formed in the portion corresponding to the area other than the through-holes of the perforated plate on at least one of both surfaces of the metal member.

3. A low expansion plate according to claim 1, wherein the convex portion is formed in the portion corresponding to each of the through-holes of the perforated plate while the concave portion is formed in the portion corresponding to the area other than the through-holes of the perforated plate on at least one of both surfaces of the metal member.

4. A low expansion plate according to claim 1, wherein the concave portion and the convex portion are formed on each of both surfaces of the metal member.

5. A low expansion plate according to claim 1, wherein the metal member is made of Cu.

6. A low expansion plate according to claim 1, wherein the metal member is made of Al.

7. A low expansion plate according to claim 1, wherein the low expansion material constituting the perforated plate is Invar.

8. A low expansion plate according to claim 1, wherein a plate thickness is 0.1 to 5 mm.

9. A method of manufacturing a low expansion plate comprising the steps of:
arranging a planar metal plate on each of both surfaces of a planar perforated plate made of low expansion material in which a plurality of through-holes are formed;
arranging a protective member on each surface of the metal plates opposite to the perforated plate;
pressurizing the protective members from each surface thereof opposite to the metal plates to depress the metal plates toward the inside of the respective thorough-holes of the perforated plate and to bond the metal plates onto both surfaces of the perforated plate; and
removing the protective members from outer surfaces of the metal plates.

10. A method of manufacturing a low expansion plate according to claim 9, wherein the protective members are made of material having a Young's modulus smaller than that of the low expansion material constituting the perforated plate and that of material constituting the metal plates.

11. A semiconductor device comprising:
the low expansion plate according to claim 1; and
a semiconductor element arranged on the concave portion and the convex portion formed on the surface of the metal member of the low expansion plate.

12. A semiconductor device according to claim 11, wherein the semiconductor element is bonded to only the convex portion formed on the surface of the metal member of the low expansion plate.

13. A semiconductor device according to claim 12, wherein a difference in height between the concave portion and the convex portion formed on the surface of the metal member is about 5 to 10 μm or larger.

14. A semiconductor device according to claim 12, wherein the semiconductor element is bonded onto the convex portion formed on the surface of the metal member of the low expansion plate by use of a solder.
